(19) United States
(12) Patent Application Publication
(10) Pub. No.: US 2025/0220944 A1
(43) Pub. Date: Jul. 3, 2025

(54) METHOD OF CONTROLLING METAL GATE HEIGHT AND SELECTIVE SPACER FORMATION

(71) Applicant: Intel Corporation, Santa Clara, CA (US)

(72) Inventors: Shao Ming Koh, Portland, OR (US); Sudipto Naskar, Portland, OR (US); Matthew Prince, Portland, OR (US); Vivek Thirtha, Portland, OR (US); Marvin Paik, Portland, OR (US)

(73) Assignee: Intel Corporation, Santa Clara, CA (US)

(21) Appl. No.: 18/397,338

(22) Filed: Dec. 27, 2023

(51) Int. Cl. H01L 29/775; H01L 27/088; H01L 29/06; H01L 29/423; H01L 29/66; H01L 29/786

(52) U.S. Cl. CPC H10D 30/43; H10D 30/014; H10D 30/6735; H10D 30/6757; H10D 62/121; H10D 64/017; H10D 84/83

(57) ABSTRACT

Integrated circuit (IC) devices with non-planar transistors may be formed from a material stack having a sacrificial layer between one or more mask material layers and a top surface of a channel material. An IC device may include a non-planar transistor with a gate spacer layer having portions with a same or consistent composition, both over an upper surface of the channel material and under a lower surface of the channel material. The gate spacer layer may have a different composition than a gate endcap spacer layer.

### BACKGROUND

A continuing pressure to shrink integrated circuit (IC) devices drives transistor densities upward and critical dimensions (CDs) downward. At progressively smaller scales, the significance of CD variation increases for many key features, such as transistor gate heights. Excessive gate heights may cause increased gate capacitances and reduced operating frequencies, but conventional manufacturing processes typically rely on highly variable etching or polishing steps to set gate heights.

New techniques, structures, and materials are needed to help reduce transistor gate heights and to minimize gate height variations.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 is a flow chart of methods for forming transistors with reduced and well-controlled metal gate heights, in accordance with some embodiments;

FIGS. 2, 3, 4, 5, 6, 7, 8, 9, 10, 11, and 12 illustrate isometric views of a transistor having a reduced-height metal gate structure over a stack of nanoribbons, at various stages of manufacture, in accordance with some embodiments;

FIG. 13 illustrates an IC device having contacts through dielectric layers over transistor structures, in accordance with some embodiments;

FIG. 14 illustrates an integrated circuit (IC) device having multiple transistor structures with gate contacts through mask material layers to gate metals, in accordance with some embodiments;

FIG. 15 illustrates a diagram of an example data server machine employing an IC device having gate spacer layers with a same composition, in accordance with some embodiments; and

FIG. 16 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices having transistors (e.g., field-effect transistors, FETs) with metal gates over channel materials, for example, over a fin in a FinFET or a nanoribbon channel in a gate-all-around (GAA) FET.

Rather than controlling gate height with a conventional etch or polish as in typical metal-gate processes, the current disclosure describes a method that sets a metal gate height with a sacrificial layer over a channel (e.g., a fin or nanoribbon) in a material stack. A well-controlled deposition of the sacrificial layer (for example, by epitaxy) enables a repeatable thickness and a reduced gate height. Reduced gate heights facilitate scaling down of IC devices and reduce parasitic capacitances, which leads to improved device performance (e.g., higher operating frequencies). The etching or polishing (e.g., chemical-mechanical polishing or planarizing, CMP) of previous methods results in large variations in gate heights, for example, across wafer, and necessarily larger gate heights and reduced performance.

A material stack may include the sacrificial material deposited to any desired thickness over a channel material. In the case of transistors with stacks of nanoribbons, the sacrificial layer can be a same material used between nanoribbon channels in the material stack. Using a same sacrificial material over and under the top nanoribbon may provide more uniform processing relative to conventional methods. More uniform processing may reduce process variation. In some embodiments, the sacrificial material includes silicon and germanium.

The material stack may include one or more hardmask layers over the sacrificial material. The hardmask layer(s) may offer etch selectivities during processing of the material stack. The hardmask layer(s), along with the sacrificial material, may also provide protection to the top of the channel material throughout processing. For example, throughout a conventional manufacturing process, the top of the channel material (e.g., the top nanoribbon in a stack) may be more exposed to etching, and the additional layer(s) described herein may offer more uniform processing of the channel material along a vertical height of the material stack. The hardmask layer(s) may also provide protection after the sacrificial material has been removed, such as to a gate dielectric over the channel material.

The hardmask layer(s) may, for example, after the gate metal has been deposited, assist with recess (e.g., CMP or etch) depth control by providing endpoint detection.

In a material stack having a hardmask over sacrificial layers over and under nanoribbons, each nanoribbon can be processed concurrently, including forming the dielectrics over and under each nanoribbon. In a typical stack, without these one or more layers over a top nanoribbon, an oxide layer may be over a top channel surface, but not lower channel surfaces. This oxide layer may have a composition (e.g., of silicon and oxygen) with a lower permittivity than the high-permittivity (“high-K”) dielectric over the channel material elsewhere (e.g., lower nanoribbons). The present disclosure provides for a structure with more consistent electrostatic control of channel conduction.

Consistent nanoribbon processing as described in the present disclosure allows for concurrent deposition of a spacer dielectric over and under each nanoribbon, which may indicate use of the disclosed method. A uniform gate spacer composition may be above and below each nanoribbon in a stack, between the gate structure and source and drain structures. In embodiments with a larger sacrificial layer thickness (and larger subsequent gate spacer cavity, following removal of some of the sacrificial material), a selective cavity spacer deposition of the gate spacer may be done.

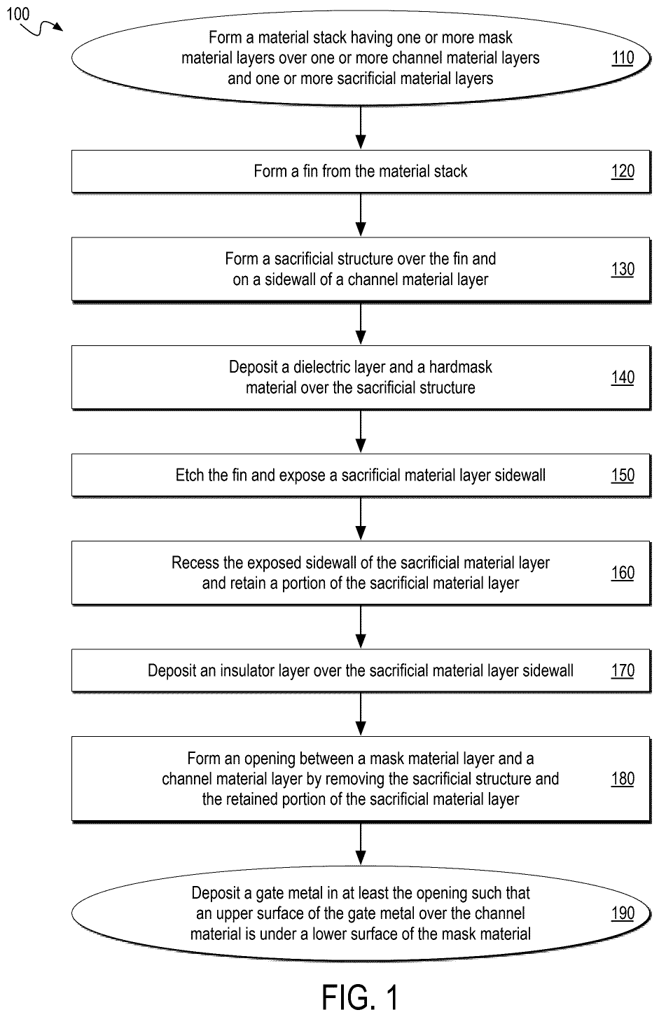

FIG. 1 is a flow chart of methods 100 for forming transistors with reduced and well-controlled metal gate heights, in accordance with some embodiments. Methods 100 include operations 110-180. Some operations shown in FIG. 1 are optional. Additional operations may be included. FIG. 1 shows an example sequence, but the operations can be done in other orders as well, and some operations may be omitted. Some operations can also be performed multiple times before other operations are performed. For example, multiple fins may be formed and etched, and multiple dummy gates may be formed over the fins. Some operations may be included within other operations so that the number of operations illustrated FIG. 1 is not a limitation of the methods 100.

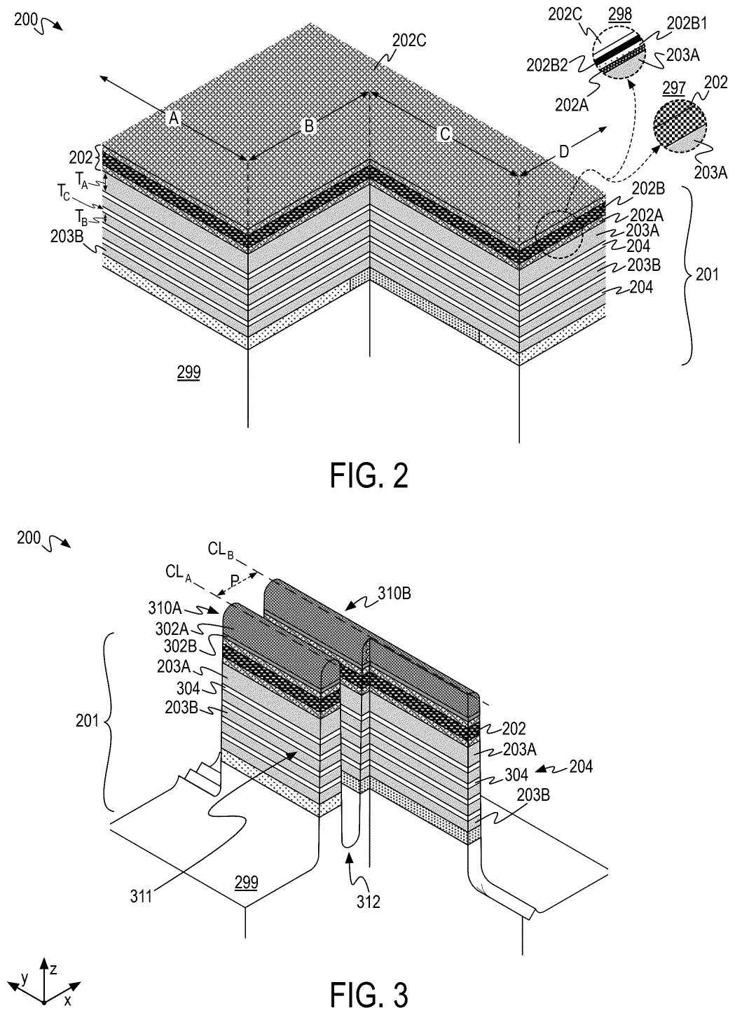

FIGS. 2, 3, 4, 5, 6, 7, 8, 9, 10, 11, and 12 illustrate isometric views of a GAAFET having a reduced-height metal gate structure over a stack of nanoribbons, at various stages of manufacture, in accordance with some embodiments. FIGS. 2-13 show possible examples of intermediate structures during an embodiment of a practice of methods 100 of FIG. 1.

Returning to FIG. 1, methods 100 begin at operation 110 with forming a stack of materials having a mask material layer over a sacrificial material layer and a channel material layer. One or more fins having at least some of the layers may be subsequently formed from the material stack, and one or more transistors may be formed with one or more channels in each fin. In at least some embodiments, a sacrificial material layer is in contact with a mask material layer and between the mask material layer and a channel material layer.

The material stack may be formed on a substrate, such as an IC die or wafer of a substantially monocrystalline material. In some embodiments, the substrate is received with the material stack already formed over a substantially monocrystalline base material. In many embodiments, the substrate is of a semiconductor (such as silicon) or insulator material. The material stack may be formed by any suitable means, for example, by depositing (e.g., by chemical vapor deposition, CVD) one layer over another. In some embodiments, forming the stack of materials includes epitaxially depositing at least some of the material layers, for example, by atomic layer deposition (ALD). Such deposition may enable precise control (e.g., to within a molecular layer or <1 nm) of the thickness of the various layers in the material stack.

The material stack may include a single, tall channel material layer (e.g., of multiple tens of nanometers), for example, in FinFET embodiments. In other embodiments, the material stack may include multiple, thin channel material layers, such as nanosheets, aligned one over the other. Channel material layers may be doped, e.g., as deposited or after deposition. Dopants may be n- or p-type impurities, depending on transistor conductivity type.

The material stack includes at least one sacrificial material layer over the channel material layer(s) and between the channel material layer(s) and one or more mask material layers. The opening formed by the eventual removal of the sacrificial material over the channel material will be the space that the metal gate is formed in, so the dimensions (e.g., thickness) of this top sacrificial material layer will determine the dimensions of the metal gate. The gate height can be made higher (or taller) by making this top sacrificial material layer thicker or made lower (or shorter) by making this top sacrificial material layer thinner. Such a top sacrificial material layer may be used to set the gate height over channels in fins or nanoribbon stacks. In some embodiments, e.g., in GAAFETs, the sacrificial material layer in contact with a mask material layer is one of a group of sacrificial material layers in a stack, and the material stack includes multiple, thin sacrificial material layers interleaved with channel material layers. In such embodiments, the thickness of the thin sacrificial material layers between channel material layers defines the spaces between the eventual nanoribbons.

The channel and sacrificial material layers may be formed by any suitable means. In some embodiments, forming the stack of materials includes alternately depositing the sacrificial and channel material layers, such that the group of sacrificial material layers are deposited interleaved with a group of transistor channel material layers. In some embodiments, forming the stack of materials includes epitaxially depositing one or both of the channel and sacrificial material layers, for example, by ALD. Such deposition provides precise control of layer thicknesses, e.g., to within <1 nm. Consequently, epitaxial deposition of the top sacrificial material layer over the channel material allows for fine and repeatable control of the eventual metal gate height. In many embodiments, most sacrificial material layers (e.g., those sacrificial material layers between channel material layers) are relatively thin. For example, sacrificial material layers between channel material layers may be around 10 nm thick or thinner. In some embodiments, the top sacrificial material layer (over the channel material and in contact with a mask material layer over the sacrificial and channel material layers) is deposited to a thickness equal to a thickness of the sacrificial material layers between the channel material layers. In some embodiments, the top sacrificial material layer is deposited to a thickness greater than a thickness of the sacrificial material layers between the channel material layers. In some such embodiments, the top sacrificial material layer is deposited to a thickness about twice a thickness of the sacrificial material layers between the channel material layers. Such a thickness may set a satisfactorily low gate height while still allowing sufficient space for gate formation. In some embodiments, the top sacrificial material layer is deposited to a thickness about 50% greater than a thickness of the sacrificial material layers between the channel material layers. Such a thickness may set an advantageously low gate height. Other layer thicknesses (and gate heights) may be set.

The material stack may be formed with one or more mask material layers over the top sacrificial material layer. A single mask material layer may be employed to act as a hardmask over the top sacrificial material layer (or other materials after sacrificial materials are removed) and to provide an etch selectivity relative to other exposed materials at various operations of methods 100. Greater thicknesses of the single mask material layer may be deposited to ensure a sufficient hardmask is maintained throughout processing. In some embodiments, a mask material stack having two, three, or more mask material layers is formed on and over the sacrificial material layer. Any additional layer(s) may provide an additional etch selectivity. For example, a mask material stack may be designed with each layer to act as a hardmask during one or more particular etches. Individual mask material layers may be deposited to correspondingly sufficient thicknesses, e.g., to withstand a given etch.

The mask material layer (or layers in a mask material stack) may be formed by any suitable means (e.g., a CVD) and to any suitable thickness. The first mask material layer (or a single mask material layer) may be formed on the sacrificial material layer over a channel material layer. One or more subsequent mask material layers may be formed over the first mask material layer, which may act as an interface layer with the sacrificial material layer. The mask material layer(s) may, but need not, be formed epitaxially or conformally. The mask material layer(s) may be formed with a blanket (or any suitable) deposition. In some embodiments, the mask material layer or stack is formed to a thickness of between two and three times a thickness of the top sacrificial material layer.

FIG. 2 shows an exemplary material stack 201 in a workpiece or IC device 200, in accordance with some embodiments, for example, following a performance of operation 110. A mask material layer 202 or stack is over sacrificial material layers 203 and channel material layers 204. Stack 201 of material layers 202, 203, 204 may be formed over a substrate 299. Note that for illustrative purposes, only selected portions of substrate 299 and layers 202, 203, 204, etc., are shown; stack 201 of material layers 202, 203, 204 continues in both x- and both y-directions. The selected portions are shown, and some sections are not shown, e.g., to illustrate transverse and longitudinal cross-sections, along lines A, B, C, D consistently throughout FIGS. 2-13 unless otherwise noted (e.g., FIG. 13, along lines A, B′, C, D).

Material stack 201 in the embodiment of FIG. 2 includes multiple channel material layers 204 interleaved between multiple sacrificial material layers 203. A top sacrificial layer 203A is in contact with mask multi-layer 202 (e.g., at mask material layer 202A) and over a top channel layer 204. Other sacrificial layers 203B are between and under channel layers 204. The embodiment of FIG. 2 includes multiple mask material layers 202A, 202B, 202C. Other embodiments include a single mask material layer 202 on top sacrificial layer 203A.

Sacrificial layers 203A, 203B have thicknesses T_{A}, T_{B}, respectively, as shown. Channel material layers 204 have thicknesses Tc. Thicknesses T_{A}, T_{B}, Tc may be well controlled through epitaxial growth processes, for example, to within <1 nm of a target thickness. In some embodiments, thickness Tc of channel layers 204 is around 10 nm or less. In some such embodiments, thickness Tc of channel layers 204 is 5 nm or less, which may enable shorter transistor stacks 201 while providing sufficient conductivity through nanoribbon channels. In some embodiments, thickness T_{B} of sacrificial layers 203 between channel layers 204 is approximately equal to thickness Tc of channel layers 204, e.g., about 5 nm. In some such embodiments, thickness T_{B} is approximately 10 nm, or twice a thickness Tc, which may allow for sufficient space for gate dielectric layers and metal between adjacent nanoribbon channels.

The eventual gate height is determined by thickness T_{A} of sacrificial layer 203A. Sacrificial layer 203A may be formed with a sufficient thickness T_{A}, for example, greater than thickness T_{B}, to provide satisfactory space over top channel layer 204 for gate formation. As described, thickness T_{A} of top sacrificial layer 203A may be half again or twice the thickness T_{B} (etc.) of other sacrificial layers 203B. In some embodiments, thicknesses T_{A}, T_{B} of sacrificial layers 203A, 203B are approximately equal. Thickness T_{A} and sacrificial layer 203A may be well controlled through a suitable deposition process, including an epitaxial growth process.

More or fewer layers 203, 204 may be deployed in other embodiments of stack 201 and device 200. In some embodiments (e.g., FinFET embodiments), a single, large channel layer 204 is under a single spacer sacrificial layer 203A. In some embodiments, a single channel material layer 204 is between sacrificial layers 203A, 203B. In many embodiments, three or four channel material layers 204 are between sacrificial layers 203. Other embodiments have more or fewer channel layers 204.

Stack 201 and layers 202, 203, 204 may include any suitable materials and have any suitable composition. In many embodiments, stack 201 is silicon-based, and some or all of layers 202, 203, 204 include silicon. In some embodiments, channel layers 204 are substantially silicon. In other embodiments, channel layers 204 include germanium (e.g., Si_{1-X}Ge_{X}, Ge_{1-X}Sn_{X}, or substantially pure Ge). In some embodiments, channel layers 204 include a transition metal and a chalcogen (such as sulfur, selenium, or tellurium). The transition metal may be any transition metal, such as any element of groups 4 through 11, group 3 elements scandium and yttrium, and the inner transition metals (e.g., f-block lanthanide and actinide series). Notable transition metals are molybdenum and tungsten. In other embodiments, channel layers 204 include one or more metals and oxygen (i.e., metal oxide semiconductor), such as indium gallium zinc oxide (IGZO). Channel layers 204 may have any suitable composition, i.e., for a channel of a FET.

Channel layers 204 are advantageously crystalline, for example, substantially monocrystalline. In some embodiments where channel layers 204 are substantially pure silicon, the crystallinity of channel layers 204 is cubic with a top surface having crystallographic orientation of (100), (111), or (110), for example. Other crystallographic orientations are also possible. Channel layers 204 may also be polycrystalline or amorphous, for example, in certain metal-chalcogen and/or metal oxide embodiments. Channel layers 204 may include an n-type impurity (such as phosphorus, arsenic, or antimony) or a p-type impurity (such as boron or aluminum).

Sacrificial layers 203 have a different composition than channel layers 204. In some examples, sacrificial layers 203 have more germanium than channel layers 204. For example, where channel layers 204 are predominantly silicon, sacrificial layers 203 are Si_{1-X}Ge_{X}, and X may be advantageously between 0.3-0.35. In other embodiments, sacrificial layers 203 have less germanium than channel layers 204. For example, where the channel layers 204 are Si_{1-X}Ge_{X}, sacrificial layers 203 may be predominantly silicon. In other embodiments where channel layers 204 include a first metal chalcogenide, sacrificial layers 203 may be of a second metal chalcogenide or a metal oxide, for example.

Sacrificial layers 203 are also advantageously crystalline. Although the crystalline semiconductor includes polycrystalline thin film material, sacrificial layers 203 may be substantially monocrystalline. In some embodiments where the crystallinity of channel layers 204 is cubic with a top surface having crystallographic orientation of (100), (111), or (110), for example, sacrificial layers 203 have this same crystallinity. Sacrificial layers 203 may also be polycrystalline or amorphous, for example in certain metal chalcogen and/or metal oxide embodiments.

Mask material layer(s) 202 may include any number of layers with each mask layer 202 having any composition known to be suitable as a hardmask. In some embodiments, a stack of mask layers 202 includes at least a bottom layer 202A and a top layer 202C. In some such embodiments, a stack of mask layers 202 includes a middle mask layer 202B between bottom and top layers 202A, 202C. In some such embodiments, bottom and top mask layers 202A, 202C may have same or similar compositions. In exemplary embodiments, mask layers 202 include silicon and at least one other majority constituent, such as oxygen (e.g., Si_{Y}O_{X}), nitrogen (e.g., Si_{Y}N_{X}) or carbon (e.g., Si_{Y}C_{X}). Bottom and top mask layers 202A, 202C may have etch selectivities relative to other mask layers (such as middle mask layer 202B). For example, bottom and top mask layers 202A, 202C may include carbon and may protect (e.g., mask) a middle mask layer 202B that includes nitrogen from operations (e.g., etches) that layer 202B is susceptible to.

In the exemplary embodiment of FIG. 2, layers 202A, 202C include silicon and carbon and have atomic compositions (by atomic percentage) of approximately 50% silicon and 50% carbon (e.g., silicon carbide). (Layers 202A, 202C include <5% nitrogen, which may be a minimum detectability level below which an atomic percentage may be considered approximately zero.) Other ratios may be employed, for example, for cost considerations or to provide etch selectivity or resistance against particular etchants. In some embodiments, layers 202A, 202C including silicon and carbon have atomic compositions of at least 30% silicon and at least 30% carbon. In the exemplary embodiment of FIG. 2, layer 202B includes silicon and nitrogen and has an atomic composition of at least 40% silicon and at least 20% nitrogen. Other compositions may be deployed, for example, to provide etch selectivities or other (e.g., electrical) characteristics (such as reduced permittivity). Hardmask layers 202A, 202C may protect middle mask layer 202B from etches directed to chemistries approximating that of layer 202B. Layer 202B (and/or layers 202A, 202C) may be used for recess endpoint detection. In many embodiments with a single mask layer 202 (e.g., layer 202A in contact with sacrificial layer 203A), mask material layer 202 includes silicon and nitrogen, e.g., having an atomic composition of at least 40% silicon and at least 20% nitrogen.

Views 297, 298 show other embodiments of mask material layer(s) 202, including a stack of layers 202. View 297 illustrates a single mask layer 202 (or bottom mask layer 202A) over and in contact with a top sacrificial layer 203A. For example, a single mask material layer 202 (or layer 202A in contact with sacrificial layer 203A) may include silicon and nitrogen as described, e.g., having an atomic composition of at least 40% silicon and at least 20% nitrogen. Such a single mask material layer 202 may have a thickness less than, greater than, or equal to other stacks of layers 202 described herein.

View 298 illustrates a stack of multiple mask layers 202 (over and in contact with a top sacrificial layer 203A) having differing compositions. As described, bottom and top mask layers 202A, 202C have a same or similar composition in some embodiments. In some embodiments, bottom and top mask layers 202A, 202C have differing compositions, which may offer processing flexibility (for example, etch selectivities with different etchants). In some embodiments, layers 202A, 202C have differing thicknesses, as may be convenient or necessary (e.g., to endure through different etches). In some embodiments, no layers 202B are between layers 202A, 202C, which may reduce process time, cost, etc. In some embodiments, multiple mask layers 202B (e.g., layers 202B1, 202B2, etc.) are between layers 202A, 202C. Such multiple layers 202B may provide more flexibility (such as more or other etch selectivities, endpoint detection for more or other recesses, etc.). Mask layers 202B may have the same or different compositions relative to other mask layers 202 (e.g., layers 202A, 202B, 202C).

More or other layers 202 may be deployed for these or other purposes. Although only three layers are illustrated in FIG. 2, stack of mask layers 202 may include any number of material layers having a total thickness that may vary with implementation, but in some examples is about 20 nm or less. In some embodiments, top sacrificial layer 203A has a thickness approximately equal to a total thickness of mask material layer(s) 202.

Returning to FIG. 1, methods 100 continue by forming a fin from the stack of materials at operation 120. The fin includes at least the first mask material in contact with the sacrificial material layer over the transistor channel material, as described of the stack of materials at, e.g., operation 110 and FIG. 2. In some embodiments, forming the fin forms a group (e.g., a stack) of nanoribbons from the group of channel material layers. In at least some such embodiments, the first sacrificial material layer is maintained over (e.g., in contact with) a top nanoribbon of the group of nanoribbons.

The fin may be formed by any suitable means, such as patterning and etching. In many embodiments, photolithography is employed to pattern fins from the stack of materials. In some such embodiments, the stack of materials is etched down to reveal a fin from the stack (or multiple parallel fins). In many embodiments, the etching may include transverse cuts across the fin(s) such that multiple fins are formed aligned along a shared centerline. Forming the fin may employ reactive-ion etching (RIE), including deep RIE (DRIE), to form fins with small pitches and nearly vertical sidewalls. Other (e.g., plasma) etching techniques may be employed.

FIG. 3 illustrates multiple fins 310 with nearly vertical sidewalls 311, in accordance with some embodiments, for example, following an execution of operation 120. Parallel fins 310A, 310B have parallel centerlines CLA, CLB along longitudinal lengths (e.g., in the y direction) and separated by a pitch P (e.g., in the x direction). FIG. 3 illustrates a transverse cross-section of fin 310A and a partial longitudinal cross-section of fin 310B. A trench 312 is between fins 310. Fins 310A, 310B have transverse widths (e.g., in the x direction). In the embodiment of FIG. 3, fins 310 and trench 312 with approximately equal widths. In some embodiments, fins 310 are notably wider than trench 312. In other embodiments, trench 312 is wider than fins 310.

Fins 310 include the materials of stack 201, for example, as described at operation 110 and FIG. 2. A patterned portion of top sacrificial layer 203A is under, and in contact with, patterned portion of mask material layer(s) 202. Channel material layers 204 are between sacrificial layers 203 and have been patterned and etched into retained nanoribbon channel regions 304. Nanoribbon channel regions 304 (of channel material layers 204) may include dopant materials. For example, channel regions 304 of adjacent fins 310 may include dopant impurities for the same or complementary conductivity types.

Although the embodiment shown in FIG. 3 includes nanoribbon channel regions 304 and multiple channel layers 204, fins 310 include a single, taller (e.g., thicker) channel layer 204 in some embodiments (e.g., in FinFET embodiments). In some such embodiments, a single sacrificial layer 203A is over channel layer 204.

Device 200 also includes lithographic mask layers 302A, 302B over, and in contact with, mask material layer(s) 202. Lithographic mask layers 302 have been patterned, and those patterns have been transferred downward (e.g., by dry etching) into layers 202, 203, 204 of stack 201.

Returning to FIG. 1, methods 100 continue at operation 130 with forming a sacrificial structure over and across the fin. For example, a dummy gate may be formed as (or part of) a sacrificial structure over the fin. A sacrificial structure, such as a dummy gate, may act as a placeholder, e.g., occupying a space that will later be filled with a gate metal. In at least some embodiments, the mask material layer(s) and the top sacrificial material layer are between the sacrificial structure and the transistor channel material. In at least some embodiments, the sacrificial structure is on a sidewall of the fin. In some such embodiments, a layer of a dielectric (such as a native oxide or passivation layer) is over the fin, including at least portions of the fin sidewall(s).

For example, before the sacrificial structure is formed, an isolation material may be deposited over the substrate to a height over a top of the fin, e.g., over the top of the mask material layer(s). The isolation material may then be recessed to some height below the fin top, but still around the fin, e.g., a shallow trench isolation (STI) to isolate channel regions in adjacent fins. A thin layer of isolation material may then be grown over a fin. The sacrificial structure then may be over bulk isolation material, e.g., STI between fins, or over a thin layer of isolation material on a fin sidewall. In some embodiments, the sacrificial structure is on a sidewall of the transistor channel material. In some such embodiments, the sacrificial structure is on an oxide or passivation layer on the sidewall of the transistor channel material.

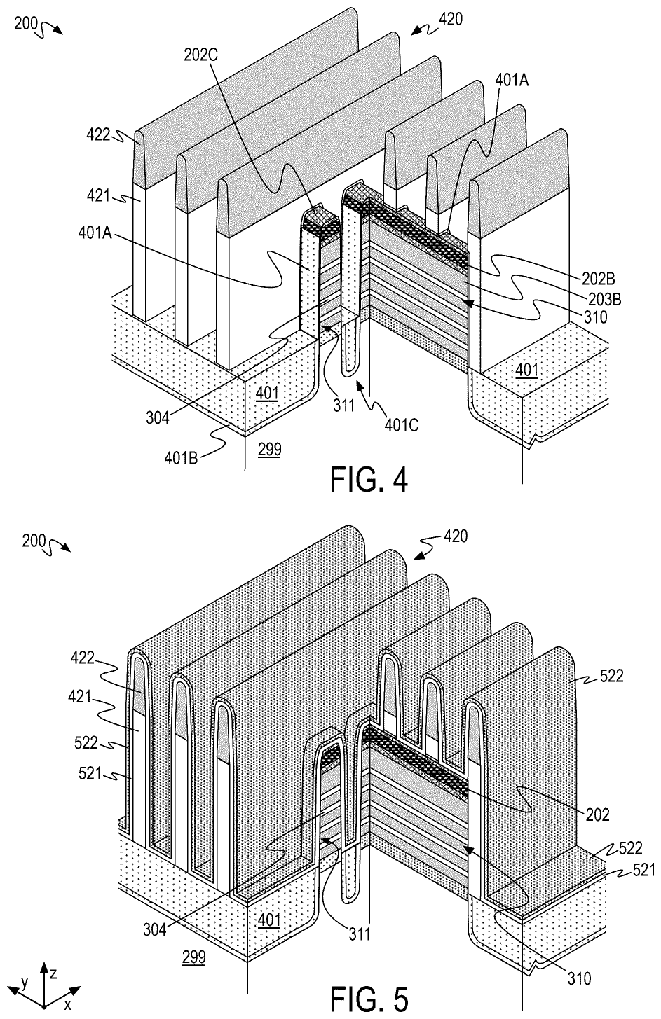

FIG. 4 shows sacrificial structures 420 in device 200, in accordance with some embodiments, for example, following a performance of operation 130. Sacrificial structure 420 includes a dummy gate 421 over and across fin 310 and may include a mask structure 422 over dummy gate 421. Sacrificial structures 420 extend longitudinally in the x-direction, perpendicular to the longitudinal y-direction of fins 310.

Sacrificial structure 420 is over isolation material 401 on and between fins 310. Bulk isolation material 401 is between and around fins 310, e.g., as an STI. A layer of isolation material 401A is over fins 310, including on sidewalls 311. A layer of isolation material 401A on sidewalls 311 is exposed between sacrificial structures 420 and covered by sacrificial structures 420 between fins 310 and sacrificial structures 420. Some of isolation material 401A may be removed, e.g., by an anisotropic etch following the formation of sacrificial structure 420. The top of fin 310, including top mask layer 202C and the highest portions of sidewalls 311 (including mask layer 202B), may be exposed by such a removal. A layer of isolation material 401B may be grown over substrate 299 before the bulk fill of isolation material 401 is deposited, and the layer of isolation material 401B may be between bulk isolation material 401 and a base material of substrate 299. Isolation material 401 includes STI isolation material 401C in a trench between fins 310.

In the example of FIG. 4, isolation material 401 is an oxide of silicon, sacrificial structure 420 includes a polysilicon dummy gate 421, and mask layers 202 include silicon. Bottom and top mask layers 202A, 202C also include carbon (e.g., >40% Si and >20% C) and a negligible or non-detectable amount of nitrogen (e.g., <5%). Middle mask layer 202B includes nitrogen (e.g., >50% Si and >20% N) and a negligible, non-detectable amount of carbon (e.g., <5%). In conventional methods (e.g., not having sacrificial layer 203B and mask layer(s) 202 of, for example, silicon nitride and/or silicon carbide), only a thin layer of isolation material 401A may be over nanoribbon channel regions 304 and the top of fins 310, which provides less protection for channel regions 304, e.g., from etching.

Returning to FIG. 1, methods 100 continue at operation 140 with depositing a dielectric layer over the sacrificial structure and the fin. In some embodiments, after the sacrificial structure is removed, portions of this dielectric layer will be kept and will eventually be on a sidewall of a metal gate structure (for example, as a gate endcap spacer). Being adjacent to the metal gate structure, the gate endcap spacer may advantageously be of a low-K dielectric material. In many embodiments, this dielectric layer includes silicon, oxygen, and carbon, but not nitrogen (e.g., >30% Si, >15% O, >5% C, and <5% N). In some embodiments, multiple dielectric layers are deposited over the sacrificial structure and the fin.

In conventional methods (e.g., without mask and sacrificial layers over a top surface of the channel material), such a dielectric layer (in some embodiments, with a thin layer of isolation material) may be over the top of the fin (and channel region(s)), which provides less protection for channel regions, e.g., from etching. In at least some embodiments presently described, this gate endcap spacer layer has a different composition than the dielectric, spacer layer in a gate cavity (e.g., between nanoribbons) and/or over the top of the fin and channel region (whether nanoribbon or otherwise).

In some embodiments, a hardmask material is deposited over the sacrificial structure and a section of the dielectric layer. For example, the hardmask material may be deposited over a top section of the dielectric layer covering the top of the sacrificial structure. Such a hardmask material may prepare and protect the workpiece for subsequent etching between the sacrificial structures, such as source-drain etches through the fin. Such a hardmask material may include nitrogen and/or a metal. In some embodiments, the hardmask material includes titanium and nitrogen. Other materials or compositions may suitably protect masked structures from etches.

FIG. 5 illustrates dielectric layers 521, 522 over sacrificial structures 420 and fins 310, in accordance with some embodiments, for example, following an execution of operation 140. Dielectric layer 522 is over dielectric layer 521. Dielectric layer 521 is over and contacts isolation material 401, sacrificial structures 420 (including dummy gates 421 and mask structures 422) and fins 310 (including on sidewalls 311 and mask layers 202 at tops of fins 310). In some embodiments, dielectric layer 521 is over device 200, and layer 522 is absent. In some embodiments, dielectric layer 521 is an interface layer 521 between dielectric layer 522 and underlying structures. In conventional methods (e.g., not having mask layer(s) 202, etc.), only dielectric layer 521 or 522 may be over nanoribbon channel regions 304 and the top of fins 310, which provides less protection for channel regions 304, e.g., from etching.

One or both of dielectric layers 521, 522 may advantageously be of one or more low-K dielectric materials. In the example of FIG. 5, low-K layers 521, 522 include silicon (e.g., 50% or more) and one or both of carbon and oxygen (e.g., >15%), but do not include appreciable amounts of nitrogen (i.e., a negligible or non-detectable amount of nitrogen, such as <5%).

In some embodiments, workpiece or device 200 includes a hardmask material (e.g., of titanium nitride) over layer 522 along the upper surfaces of sacrificial structures 420. In some such embodiments, the hardmask material is blanket deposited and is additionally on layers 521, 522 over STI material 401.

Returning to FIG. 1, methods 100 continue at operation 150 by etching (e.g., cutting) the fin, for example, at unmasked sections, e.g., between sacrificial structures (e.g., dummy gates), which may be masked by hardmasks. Such etches may be recognized as source-drain etches. In some embodiments, the sacrificial structures (including dummy gates and any masks and/or material layers over the dummy gates, etc.) act as masks. In at least some such embodiments, portions of channels layers under sacrificial structures (and associated hardmasks) are retained.

Etching the fin may be with one or more dry etches, for example, by anisotropic RIE (including DRIE). Such an anisotropic etch may remove a section of the dielectric layer(s) over a fin and not masked by the hardmask material. Such an etch may retain any section of the dielectric layer covered (i.e., masked) by the hardmask material. For example, in many embodiments, the sections of the dielectric layer adjacent the sacrificial structures (e.g., dummy gates) are retained. These sections of the dielectric layer will be adjacent the eventual metal gate structure (for example, as gate endcap spacers).

In at least some embodiments, etching the fin exposes a sidewall (e.g., a substantially vertical face) of the sacrificial material. Exposing the sidewall of the sacrificial material prepares the sacrificial material for removal. In some embodiments, etching the fin exposes the sidewalls of the entire group of sacrificial material layers over and between channel layers. In some such embodiments, etching the fin exposes all of the sidewalls on both sides of the group of sacrificial material layers, e.g. on both sides of the sacrificial structures (e.g., dummy gates).

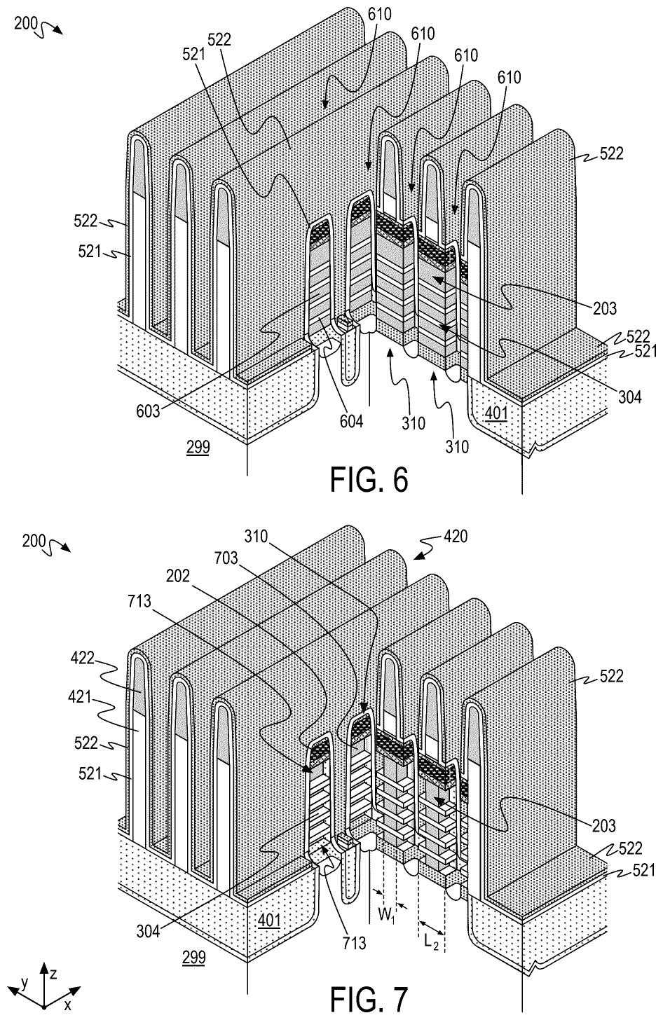

FIG. 6 shows shortened fins 310 and nanoribbon channel regions 304, in accordance with some embodiments, for example, following a performance of operation 150. For example, etched (e.g., cut) fins 310 are shorter (e.g., than before operation 150) with trenches or cuts 610 separating new, shorter fins 310. FIG. 6 illustrates longitudinal cross-sections of some cut fins 310 (e.g., on a y-z viewing plane) for illustrative purposes. Transverse cuts 610 (e.g., along x-z planes) expose sidewalls 603, 604 (such as end faces) of interleaved sacrificial layers 203 and nanoribbon channel regions 304.

Sections of dielectric layers 521, 522 not masked by (since-removed) hardmask material are absent, e.g., between (and not over) sacrificial structures 420 and previously over fins 310. Sections of dielectric layers 521, 522 masked by (since-removed) hardmask material are present, e.g., over sacrificial structures 420.

Returning to FIG. 1, methods 100 continue with recessing the exposed sidewall of the sacrificial material layer at operation 160. In some embodiments, a portion of the sacrificial material layer is retained. This recessing may be by a recess or dimple etch and may open a recess or cavity (i.e., a “dimple”) by removing a portion of sacrificial material (e.g., on the exposed sidewall) and retaining another portion of sacrificial material. Such a recess or dimple may be vertically between adjacent channel material layers (or at least over or under a channel layer). The retained portion may be a portion newly exposed by the removal of the previously exposed portion. For example, the sacrificial material may be recessed back (e.g., from an exposed sidewall or face flush with a vertical dielectric layer) to the retained portion such that a recessed sidewall (newly exposed) is approximately aligned with a sidewall of a dummy gate. In some embodiments, the material stack includes a group of multiple sacrificial material layers, each layer with at least an exposed sidewall, and the entire group of sidewalls of the group of sacrificial material layers are recessed. A portion of each of the group of sacrificial material layers is retained.

In most embodiments, the group of sacrificial material layers has exposed sidewalls on multiple sides, for example, opposing pairs of exposed sidewalls on either side of corresponding sacrificial material layers. In at least some such embodiments, all of the exposed sidewalls (e.g., for an entire group of sacrificial layers, and on both sides of a dummy gate) are recessed, and a corresponding group of portions of sacrificial material layers is retained. The group of retained portions of sacrificial material may then be that sacrificial material between the newly formed cavities or recesses and having a pair of recessed, newly exposed sidewalls.

The recessing may be by any suitable means. In some embodiments, the recessing is done by an isotropic etch selective to the sacrificial material. Such an etch may recess back the sacrificial material to a retained, newly exposed portion, but also retain or keep channel material layers above and/or below the retained sacrificial material.

Notably, at this stage of a conventional process, a dielectric layer may be over the top surface of a channel material layer (such as a nanoribbon), and subsequent deposition of a spacer layer between nanoribbons may be of a different material. For example, the top dielectric layer may be optimized to protect a top nanoribbon during processing, while cavity gate spacer material between nanoribbons may be optimized for electrical performance, e.g., as a dielectric between a gate structure and source and drain structures. As described, the present disclosure includes a recess cavity both above and below a top nanoribbon. Such cavities allow for the deposition (described below) of a same spacer dielectric material above and below the top nanoribbon. Such matched material compositions above and below the top nanoribbon may indicate the use of this disclosed method.

FIG. 7 illustrates recesses 713 adjacent retained portions 703 of sacrificial material layers 203, in accordance with some embodiments, for example, following an execution of operation 160. Recesses 713 are between nanoribbon channel regions 304, under a lowest nanoribbon channel region 304, and over an uppermost nanoribbon channel region 304 (between uppermost nanoribbon channel region 304 and mask layer(s) 202). Retained portions 703 of sacrificial material layers 203 are adjacent and between (e.g., in the y-direction) recesses 713.

At least in the embodiment of FIG. 7, sacrificial material layers 203 have been recessed such that retained portions 703 have a length (in the y-direction) approximately equal to a width W₁ of dummy gates 421. Mask layers 202 and nanoribbon channel regions 304 have equal lengths L₂ (in the y-direction). Each of recesses 713 has a dimension in the y-direction approximately equal to half of the difference between width W₁ and length L₂. Each of recesses 713 has a width in the x-direction equal to the transverse fin width (e.g., between dielectric layer 521 overlapping fin 310). Each of recesses 713 has a height in the z-direction equal to the height of the corresponding retained portions 703 of sacrificial material layers 203. In some embodiments, recesses 713 over top nanoribbon channel regions 304 have a height in the z-direction greater than a height of other recesses 713.

Returning to FIG. 1, methods 100 continue by depositing a gate spacer layer over (e.g., on) the recessed sidewall of the sacrificial material layer at operation 170. The gate spacer layer is an insulator layer that will eventually separate a gate structure from a source or drain structure. Gate spacer layers will be on both sides of the gate structure, one such layer between the gate structure and the source structure and the other layer between the gate structure and the drain structure. At a minimum, a gate spacer layer is deposited over the sacrificial material layer over the top channel material surface (e.g., a top of a fin or a top nanoribbon), immediately beneath a mask material layer. Gate spacer layers may be deposited on the recessed sidewalls of multiple sacrificial material layers (e.g., in dimpled recesses), over and under each nanoribbon. A nanoribbon may be between, and separate, adjacent portions of the gate spacer layer. Gate spacer layers may be deposited (e.g., in dimpled recesses) laterally between (i.e., in the x-direction) dielectric layer(s), such as those layers deposited over both sides of the fin at operation 140.

Gate spacer layers (e.g., portions of gate spacer between adjacent nanoribbons) may be deposited concurrently on each of the recessed sidewalls of multiple sacrificial material layers, in each of the dimpled recesses. Because of the concurrent deposition of the gate spacer layers with a same insulator material, each of the individual gate spacer layers may have a substantially same composition. Such matched material compositions (e.g., above and below the top nanoribbon) may indicate the use of this disclosed method. In conventional processes, gate spacer layers in the cavities between nanoribbons have a different composition than the insulator (e.g., low-k dielectric) layer over the top nanoribbon.

Any suitable deposition techniques and reactants may be employed. In some embodiments, the gate spacer layer is conformally deposited on the sacrificial material layer. In some embodiments, the gate spacer layer is deposited by a CVD, such as an ALD. In some embodiments, an etch is done following gate spacer deposition to remove residue deposition, e.g., on dielectric layer 522. Area-selective depositions may be advantageous in embodiments having certain recess geometries. For example, deposition techniques and chemistries to grow gate spacer layers selectively may be utilized in embodiments having larger recesses over top nanoribbons. In some embodiments, the gate spacer layer is selectively deposited by an ALD. In some embodiments, the gate spacer layer is selectively deposited on the sacrificial material layer, e.g., by an ALD. In some such embodiments, both the gate spacer layers and the sacrificial material layers include silicon. In some such embodiments, the gate spacer layers include nitrogen and oxygen, and the sacrificial material layers include germanium.

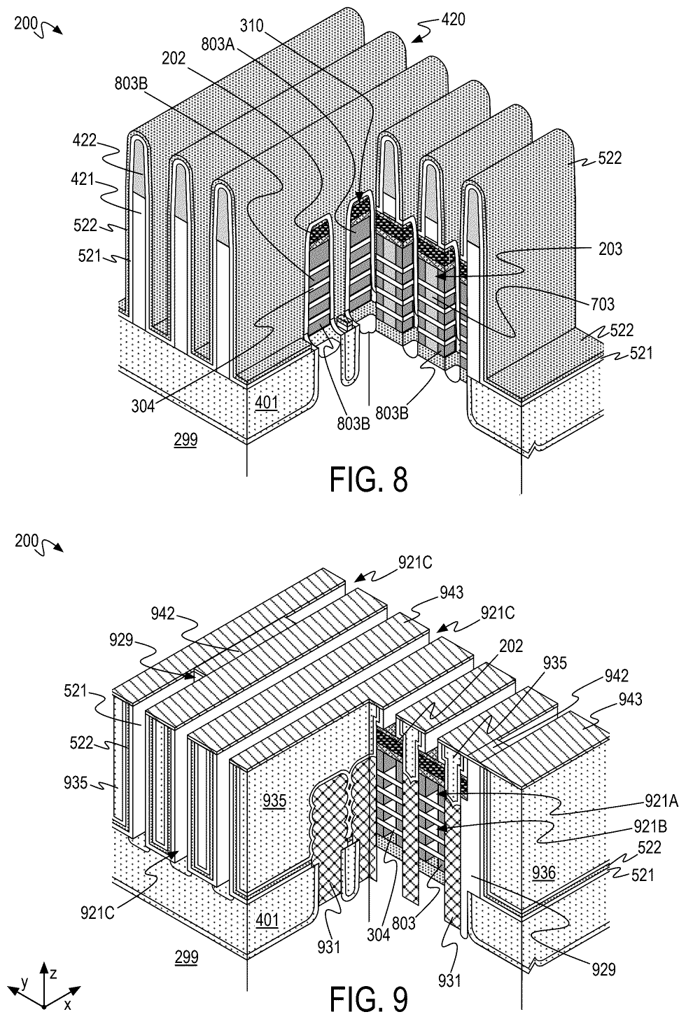

FIG. 8 shows gate spacer layers 803A, 803B on retained portions 703 of sacrificial material layers 203 and over and under nanoribbon channel regions 304, in accordance with some embodiments, for example, following a performance of operation 170. Gate spacer layers 803A are over top nanoribbon channel regions 304 and have a taller z-height than other gate spacer layers 803B. Gate spacer layers 803A, 803B have a same composition (e.g., over and under nanoribbon channel regions 304). In the exemplary embodiment of FIG. 8, gate spacer layers 803 include silicon, nitrogen, and oxygen and were selectively deposited on retained portions 703 of sacrificial material layers 203, which include silicon and germanium.

Gate spacer layers 803 are positioned to provide electrical insulation between subsequently formed gate structures and source and drain structures. Gate spacer layers 803 are also positioned to provide mechanical (e.g., structural) support to the stack of nanoribbon channel regions 304 in place of portions 703 of sacrificial material layers 203, which will be removed and replaced by gate metal. Sacrificial structures 420 (including dummy gates 421) will also be removed and replaced by gate metal. Source and drain structures may be grown from exposed ends of nanoribbon channel regions 304.

Returning to FIG. 1, methods 100 continue at operation 180 with forming an opening between the mask material layer and the channel material layer. In some embodiments, the opening is formed by removing the retained portion of the sacrificial material layer. The channel material layers (e.g. nanoribbons) may be released by this removal of the abutting sacrificial material. The opening or cavity formed is vertically between the mask material layer and the channel material layer and laterally between the paired gate spacer layers that were on either side of retained portion of the sacrificial material layer.

Any suitable means may be used to remove the sacrificial material. In some embodiments, the remaining portion of the sacrificial material layer is removed by an isotropic etch selective to the sacrificial material. In some embodiments, the remaining portion of the sacrificial material layer is removed by an atomic layer etch (ALE).

The opening between the under surface of the mask material layer(s) and the top channel material layer may be part of a larger opening formed by also removing the sacrificial structure (e.g., dummy gate) covered by dielectric layer(s). In many embodiments, the sacrificial structure is removed before removing the remaining portion of the sacrificial material layer. Removal of the dummy gate and any materials over the dummy gate may be necessary to access the remaining portion of the sacrificial material layer for removal as described. For example, the remaining portion of the sacrificial material layer may be covered by a dummy gate (e.g., in the x-directions) and gate spacer layers (e.g., in the y-directions).

Any suitable means may be used to remove the sacrificial structures. In some embodiments, multiple means are employed. For example, a CMP may reduce a height of the sacrificial structures down to the dummy gates. In many embodiments, for at least structural reasons, the source-drain trenches (between adjacent dummy gates and associated dielectric layers) are filled before the CMP. Source-drain epitaxial regions may be grown in the trenches, on the ends of channel regions. The trenches may then be filled with dielectric, e.g., over the tops of the epitaxial regions and to about the tops of the sacrificial structures. A CMP may then remove mask, dielectric, etc., material down to the dummy gates. An etch may then be utilized to remove the dummy gates, for example, an etch selective to the material of the dummy gates (such as polysilicon). In some embodiments, the dummy gates are removed with an anisotropic dry etch (e.g., a RIE). In some such embodiments, the same or another etch exposes the remaining portion of the sacrificial material layer by removing a passivation or oxide layer over the sacrificial material. In some embodiments, an etch removing a passivation or oxide layer over the sacrificial material also removes the passivation or oxide layer from over sidewalls of the channel regions (e.g., nanoribbons).

FIG. 9 illustrates gate cavities 921 between dielectric layers 521, between gate spacer layers 803, and over and under nanoribbon channel regions 304, in accordance with some embodiments, for example, following an execution of operation 180. Sacrificial material layers are absent, and nanoribbon channel regions 304 are released. Gate cavities 921 are openings where the sacrificial materials and/or structures have been removed in preparation for forming gate structures. Gate cavities 921A, 921B are between gate spacer layers 803. Gate cavities 921A are between gate spacer layers 803, over top nanoribbon channel regions 304 and under mask material layers 202. Gate cavities 921B are under nanoribbon channel regions 304, between gate spacer layers 803. Dummy gates and their sacrificial structures are absent, and gate cavities 921C (which may be referred to as fin trenches) are between dielectric layers 521. Gate cavities 921A, 921B, 921C are collectively continuous, e.g., connected at fin edges in the fin trenches.

Source or drain epitaxial regions 931 are on, and coupled to, ends of nanoribbon channel regions 304. Source or drain epitaxial regions 931 are in the source-drain trenches with trench dielectric fill 935. Dielectric layer 522 is between trench dielectric fill 935 and dielectric layer 521. Some of fill 935, such as upper portions, may be sacrificial material that occupies space and provides mechanical support, but will later be removed so that contacts can be made to regions 931. In some embodiments, trench dielectric fill 935 may be on and in a dielectric liner layer on dielectric layer 522.

In some embodiments, fin trench isolation (FTI) 929 is formed to isolate fins (including fin components and materials, such as channel regions 304) from adjacent structures, including other fins. For example, isolation 929 may be formed by depositing an electrically insulating material in a fin trench cavity 921C rather than a gate structure. Any fin components (such as channel regions 304) may be removed (e.g., by etch) before depositing the insulating material in cavity 921C. In some embodiments, FTI 929 are formed at later stages in methods 100. In some embodiments, dielectric or isolation fill 936 is adjacent FTI 929, e.g., beyond fins, channel regions 304, and source or drain epitaxial regions 931. In some embodiments, trench dielectric fill 935 and isolation fill 936 have a same composition.

Hardmasks 942, 943 are over device 200, e.g., following an etch removing dummy gates between dielectric layers 521, 522 and fill 935. Hardmasks 942 are over FTI 929. Hardmasks 943 are over dielectric layers 521, 522 and fill 935. In some embodiments, hardmasks 942, 943 include one or more metals (such as tungsten). In some such embodiments, hardmasks 942, 943 are seed materials for subsequent formation of metal fill over device 200, including in gate cavities 921.

Returning to FIG. 1, methods 100 continue by depositing a gate metal in the openings, e.g., gate cavities, at operation 190. The gate metal is deposited in the gate cavity or cavities vacated by the sacrificial layer(s), including the cavity under the mask material layer(s) and over a top surface of the channel material, such that an upper surface of the gate metal over the transistor channel material is under a bottom surface of the mask material layer(s). In this way, rather than by a highly variable etch or CMP operation, methods 100 enable precise control of the gate metal height over the channel material. The gate metal is deposited into the space occupied by the sacrificial material, whose z-height over the channel material may have been set by a precisely controlled growth process, such as an epitaxial deposition, as described at least at operation 110.

Gate metal may also be deposited in cavities vacated by sacrificial structures, including dummy gates. Gate cavities adjacent channel material may be part of larger openings, continuous with spaces occupied (and then vacated) by dummy gates, as described at operation 180.

The gate metal may be deposited by any suitable means and may include any suitable materials. For example, besides being sufficiently conductive, gate metals may be chosen and placed for work-function purposes (e.g., to influence or set a transistor threshold voltage). The gate metal may include one or more liner layers adjacent to the channel material and fill or bulk metal grown over or from a liner (e.g., seed) layer. The liner layer(s) (e.g., including titanium or tantalum in TIN, TaN, TiAIC, etc.) may be deposited conformally (e.g., by an ALD). In many embodiments, a liner layer of gate metal is deposited conformally over a conformal gate dielectric layer over at least the channel material, such as a high-K gate dielectric. Such a conformal gate dielectric layer may be deposited over the channel material (or a passivation layer over the channel material), e.g., by an ALD. A bulk metal fill (e.g., of tungsten or another metal) may be grown over a top liner layer.

In some embodiments, gate metal is deposited to a height above the bottom of the mask material layer(s) and subsequently recessed down using a mask material layer. For example, gate metal may be deposited to some taller or higher height on both sides of the fins (e.g., on both sides of the mask material and channel material layers). The gate metal may also be deposited over the mask material layer(s). The gate metal may then be recessed down (e.g., by a CMP) to a certain height using a material of a mask layer for endpointing the recess. In some embodiments, gate metal is recessed down to the bottom (or only) mask material layer. In some such embodiments, a subsequent recess may be then be performed (with or without endpointing), down to a layer below the mask material layer(s), such as a gate dielectric layer or the gate metal. In some embodiments, gate metal is recessed down to the top mask material layer in a multi-layer stack of mask layers. One or more further recesses may follow. In some embodiments, gate metal is recessed down to a mask material layer between top and bottom layers in a multi-layer stack of three or more mask layers. In some such embodiments, multiple mask layers are deployed in a multi-layer stack of mask material layers for use as etch-stop or endpoint layers, e.g., for use in multiple recesses. In some embodiments, an etch forms an opening through one or more mask material layers, and additional gate metal (e.g., a gate metal contact) is deposited in the opening, forming a metal contact to the gate metal through the one or more mask material layers. In some such embodiments, such an etch and contact formation occurs following further recessing.

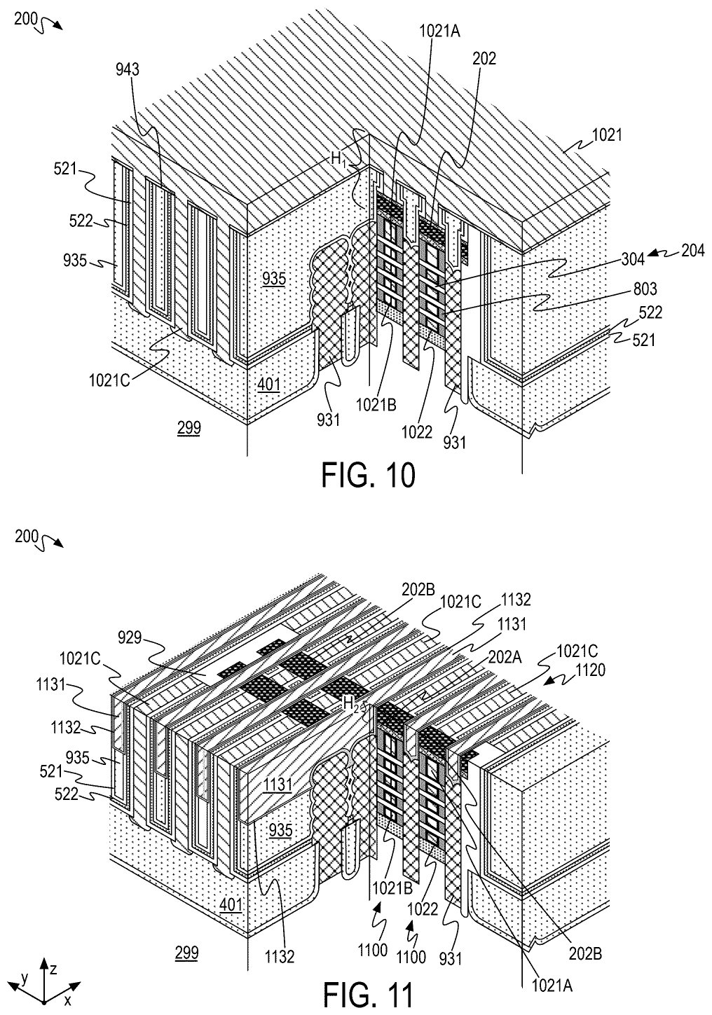

FIG. 10 shows gate metal 1021 adjacent nanoribbon channel regions 304, in accordance with some embodiments, for example, following a performance of operation 190. An upper surface of gate metal 1021A over a top nanoribbon channel region 304 (e.g., of channel material 204) is under a bottom surface of mask material layers 202. For example, gate metal 1021A may be separated from a bottom mask material layer 202 by a thin gate dielectric layer 1022. Gate metal 1021B is under nanoribbon channel regions 304, including between adjacent nanoribbon channel regions 304. Gate dielectric layer 1022 is between gate metal 1021B and nanoribbon channel regions 304. Gate metal 1021C fills fin trenches between dielectric layers 521 (between dielectric layers 522). Gate metals 1021A, 1021B, 1021C form a collectively continuous metal 1021. Trench dielectric fill 935 is in source-drain trenches between dielectric layers 522 (between dielectric layers 521).

Gate metal 1021 is over the entire shown structure of device 200, including fill 935 in the source-drain trenches. Gate metal 1021 is up to a height H1 above the lower surface of lowest of mask material layers 202. Gate metal 1021 may be recessed down (e.g., by CMP) to expose dielectric fill 935 over source and drain regions 931 in source-drain trenches. Any such recess may utilize one of mask layers 202 to control the recess depth. One or more contact etches (e.g., selective to the material(s) over regions 931, such as dielectric fill 935) may expose source and drain regions 931. Metal may be deposited over exposed source and drain regions 931.

FIG. 11 illustrates gate metal 1021C exposed and recessed down to a height H2 at mask material layer 202B over mask material layer 202A, in accordance with some embodiments, for example, following a CMP using layer 202B for endpoint detection. Another recess (e.g., an etch or CMP) may use mask material layer 202A for endpoint detection. In some embodiments, gate metal 1021C is recessed down to a lower height H2 at mask material layer 202A, e.g., approximately at either a top or bottom surface of layer 202A. Such endpoint detection advantageously enables precise control of recess depth and so the height of gate metal 1021C (e.g., to the sides of layers 202, channel regions 304, and gate metals 1021A, 1021B). Gate metals 1021A, 1021B are coupled by gate metal 1021C, e.g., at the sides or ends of gate metals 1021A, 1021B.

Source and drain metals 1131, 1132 are on regions 931 and recessed down to height H2. Precise control of the height of metals 1131, 1132 is also enabled by layers 202. Isolations 929 are also exposed and recessed down to height H2 at mask material layer 202B.

Transistor structures 1100 are illustrated in cross-section, each with a gate structure 1120 (includes gate dielectric layers 1022 and gate metals 1021A, 1021B) over and adjacent a stack of nanoribbon channel regions 304 coupling source and drain epitaxial regions 931 and corresponding source and drain metals 1131, 1132.

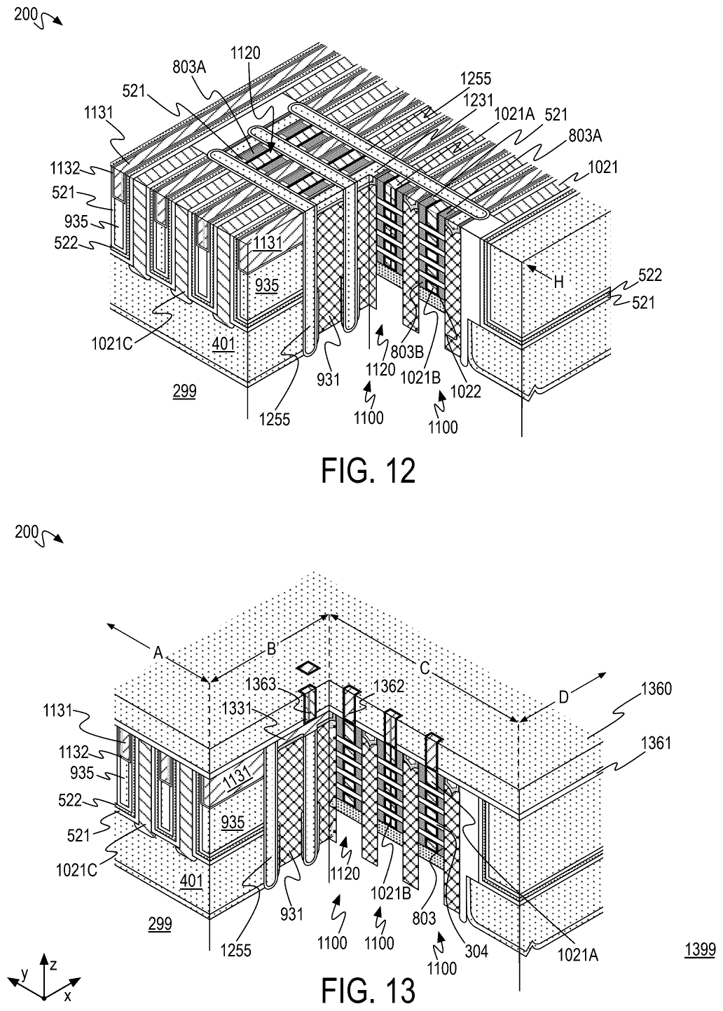

FIG. 12 shows exposed gate metals 1021A, 1021C recessed down to a height H3 below a now-removed mask material layer(s) over gate metal 1021A, in accordance with some embodiments, for example, following a recess using a mask layer for endpoint detection. The entire top surface of device 200 (for example, the top surfaces of metals 1131, 1132 and layers 521, 522, 803, 1022) may be recessed concurrently with metals 1021, e.g., using mask layers over gate metal 1021 for endpoint detection. Further recessing (e.g., by CMP) may be done following a recess to a mask layer (e.g., to approximately a bottom surface of a bottom mask layer). Only a brief, well-controlled recess may be required, for example, to remove a thin gate dielectric layer 1022. In some embodiments, one or more mask material layers are retained over gate metal 1021A. In some embodiments, an etch forms an opening through one or more mask material layers, and additional gate metal (e.g., a gate metal contact) is deposited in the opening, forming a metal contact to the gate metal through the one or more mask material layers.

In some embodiments, gate cut isolations 1255 separate adjacent transistor structures 1100. Isolations 1255 may be electrically insulating materials, such as low-K dielectric materials, deposited following deep, anisotropic etches through metals 1021, 1131. Isolations 1255 separate gate structures 1120 and epitaxial regions 931 from adjacent fins. Gate metals 1021A, 1021B are separated from gate metal 1021C by isolation 1255.

In some embodiments, some transistor structures 1100 have at least some contacts removed, e.g., depopulated. Depopulated transistor structures 1100 may be dummy transistor structures 1100, e.g., fabricated to minimize process variation, where no circuit components or connections are called for in a given design. In some such embodiments, selected source or drain metals 1131 are removed and replaced with dielectric fill 1231.

As illustrated between gate cut isolations 1255, dielectric layer 521 is between gate structure 1120 (e.g., gate metal 1021A) and source or drain region 931 (under metal 1131 or fill 1231). Dielectric layer 521 is adjacent both the upper and lower portions of gate spacer layer 803. (The upper portion is gate spacer layer 803A over an upper surface of top nanoribbon channel region 304, and the lower portion is gate spacer layer 803B, under a lower surface of a nanoribbon channel region 304.)

FIG. 13 illustrates IC device 200 having contacts 1362, 1363 through dielectric layers 1360, 1361 over transistor structures 1100, in accordance with some embodiments. Note that the selected portions shown are along lines A, B′, C, and D (i.e., along line B′, which shows transistor structure 1100 with a populated metal 1331, rather than line B). The longer cross-section along line C also shows an extra gate structure 1120.

Gate contacts 1362 couple gate structure 1120 at gate metal 1021A. Source and drain contacts 1363 couple source and drain metal 1331, which couples source and drain epitaxial regions 931, e.g., through isolation 1255 between regions 931. Contacts 1362, 1363 may include liner and bulk metal, much as previously described other metals.

Unlike in typical GAAFET devices, gate spacer layer 803 over the top nanoribbon channel region 304 has a same composition as gate spacer layers 803 between nanoribbon channel regions 304 and under bottom nanoribbon channel region 304. Gate spacer layers 803 have a composition different than dielectric (gate endcap spacer) layers 521.

IC device 200 may be coupled to a substrate 1399 and a power supply (not shown) through substrate 1399. Substrate 1399 may be any suitable structure, e.g., any host component for mounting and supporting device 200. For example, substrate 1399 may be a large IC die, a package substrate, or a motherboard.

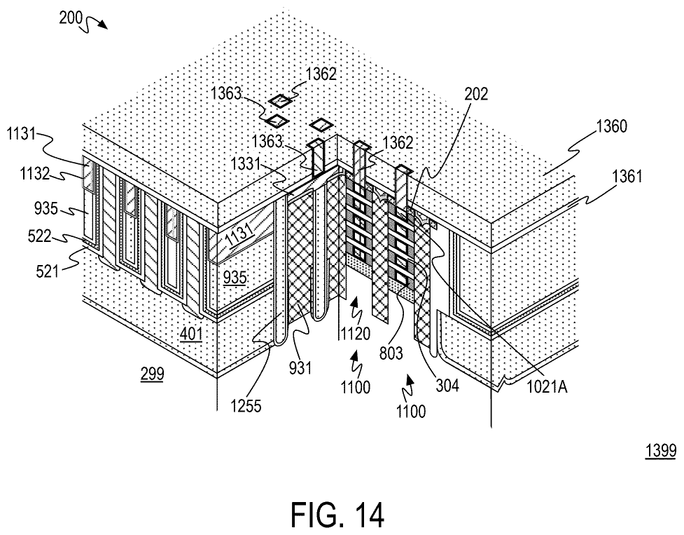

FIG. 14 illustrates IC device 200 having multiple transistor structures 1100 with gate contacts 1362 through mask material layers 202 to gate metals 1021A, in accordance with some embodiments. FIG. 14 illustrates an embodiment of device 200 similar to that shown at FIG. 13, but at least portions of one or more mask material layers 202 have been retained over gate metal 1021A and gate structure 1120. Gate contacts 1362 are through dielectric layers 1360, 1361 over transistor structures 1100, as well as through one or more mask material layers 202.

Unlike in typical GAAFET devices, gate spacer layer 803 over the top nanoribbon channel region 304 has a same composition as gate spacer layers 803 between nanoribbon channel regions 304 and under bottom nanoribbon channel region 304. Gate spacer layers 803 have a composition different than dielectric (gate endcap spacer) layers 521.

IC device 200 is coupled to a substrate 1399 and a power supply (not shown) through substrate 1399.

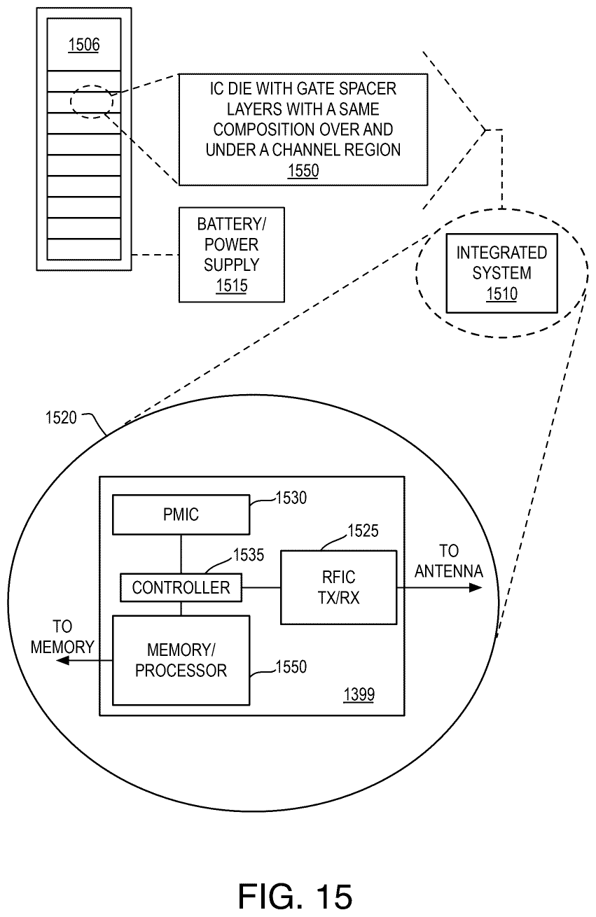

FIG. 15 illustrates a diagram of an example data server machine 1506 employing an IC device having gate spacer layers with a same composition, in accordance with some embodiments, e.g., formed from a material stack having mask and sacrificial material layers over the channel material. Server machine 1506 may be any commercial server, for example, including any number of high-performance computing platforms disposed within a rack and networked together for electronic data processing, which in the exemplary embodiment includes one or more devices 1550 having gate spacer layers with a same composition.

Also as shown, server machine 1506 includes a battery and/or power supply 1515 to provide power to devices 1550, and to provide, in some embodiments, power delivery functions such as power regulation. Devices 1550 may be deployed as part of a package-level integrated system 1510. Integrated system 1510 is further illustrated in the expanded view 1520. In the exemplary embodiment, devices 1550 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 1550 is a microprocessor including a static RAM (SRAM) cache memory. As shown, device 1550 may be an IC device having gate spacer layers with a same composition, as discussed herein. Device 1550 may be further coupled to (e.g., communicatively coupled to) a board, an interposer, or a substrate 1399 along with, one or more of a power management IC (PMIC) 1530, RF (wireless) IC (RFIC) 1525 including a wideband RF (wireless) transmitter and/or receiver (TX/RX) (e.g., including a digital baseband and an analog front end module further includes a power amplifier on a transmit path and a low noise amplifier on a receive path), and a controller 1535 thereof. In some embodiments, RFIC 1525, PMIC 1530, controller 1535, and device 1550 include having gate spacer layers with a same composition.

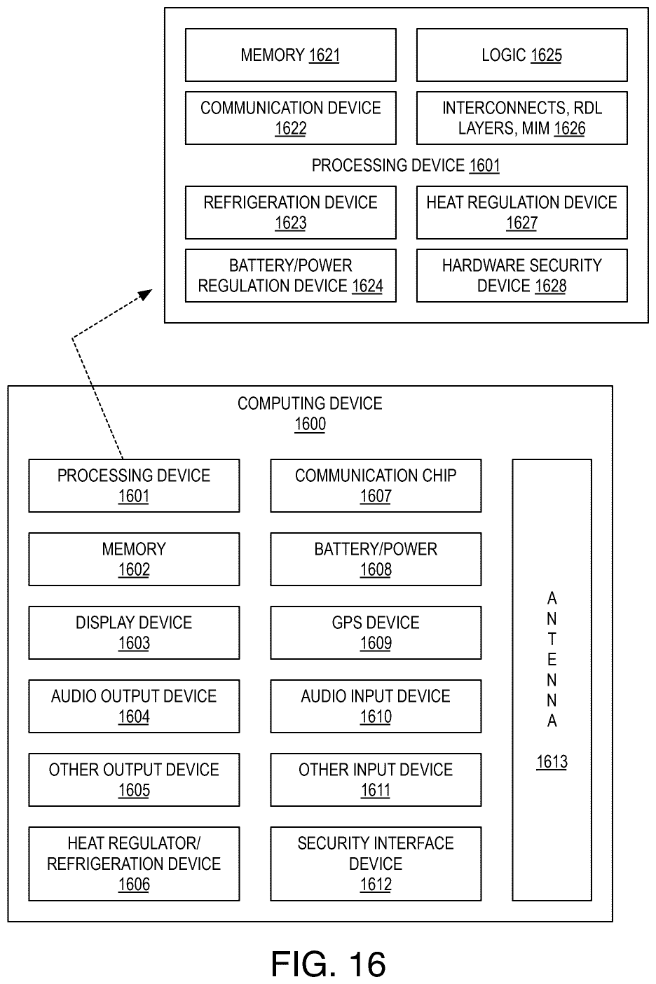

FIG. 16 is a block diagram of an example computing device 1600, in accordance with some embodiments. For example, one or more components of computing device 1600 may include any of the devices or structures discussed herein. A number of components are illustrated in FIG. 16 as being included in computing device 1600, but any one or more of these components may be omitted or duplicated, as suitable for the application. In some embodiments, some or all of the components included in computing device 1600 may be attached to one or more printed circuit boards (e.g., a motherboard). In some embodiments, various ones of these components may be fabricated onto a single system-on-a-chip (SoC) die. Additionally, in various embodiments, computing device 1600 may not include one or more of the components illustrated in FIG. 16, but computing device 1600 may include interface circuitry for coupling to the one or more components. For example, computing device 1600 may not include a display device 1603, but may include display device interface circuitry (e.g., a connector and driver circuitry) to which display device 1603 may be coupled. In another set of examples, computing device 1600 may not include an audio output device 1604, other output device 1605, global positioning system (GPS) device 1609, audio input device 1610, or other input device 1611, but may include audio output device interface circuitry, other output device interface circuitry, GPS device interface circuitry, audio input device interface circuitry, audio input device interface circuitry, to which audio output device 1604, other output device 1605, GPS device 1609, audio input device 1610, or other input device 1611 may be coupled.

Computing device 1600 may include a processing device 1601 (e.g., one or more processing devices). As used herein, the term “processing device” or “processor” indicates a device that processes electronic data from registers and/or memory to transform that electronic data into other electronic data that may be stored in registers and/or memory. Processing device 1601 may include a memory 1621, a communication device 1622, a refrigeration device 1623, a battery/power regulation device 1624, logic 1625, interconnects 1626 (i.e., optionally including redistribution layers (RDL) or metal-insulator-metal (MIM) devices), a heat regulation device 1627, and a hardware security device 1628.

Processing device 1601 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1600 may include a memory 1602, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1602 includes memory that shares a die with processing device 1601. This memory may be used as cache memory and may include embedded dynamic random-access memory (eDRAM) or spin transfer torque magnetic random-access memory (STT-MRAM).

Computing device 1600 may include a heat regulation/refrigeration device 1606. Heat regulation/refrigeration device 1606 may maintain processing device 1601 (and/or other components of computing device 1600) at a predetermined low temperature during operation.

In some embodiments, computing device 1600 may include a communication chip 1607 (e.g., one or more communication chips). For example, the communication chip 1607 may be configured for managing wireless communications for the transfer of data to and from computing device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1607 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1607 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1607 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1607 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1607 may operate in accordance with other wireless protocols in other embodiments. Computing device 1600 may include an antenna 1613 to facilitate wireless communications and/or to receive other wireless communications (such as AM or FM radio transmissions).

In some embodiments, communication chip 1607 may manage wired communications, such as electrical, optical, or any other suitable communication protocols (e.g., the Ethernet). As noted above, communication chip 1607 may include multiple communication chips. For instance, a first communication chip 1607 may be dedicated to shorter-range wireless communications such as Wi-Fi or Bluetooth, and a second communication chip 1607 may be dedicated to longer-range wireless communications such as GPS, EDGE, GPRS, CDMA, WiMAX, LTE, EV-DO, or others. In some embodiments, a first communication chip 1607 may be dedicated to wireless communications, and a second communication chip 1607 may be dedicated to wired communications.

Computing device 1600 may include battery/power circuitry 1608. Battery/power circuitry 1608 may include one or more energy storage devices (e.g., batteries or capacitors) and/or circuitry for coupling components of computing device 1600 to an energy source separate from computing device 1600 (e.g., AC line power).

Computing device 1600 may include a display device 1603 (or corresponding interface circuitry, as discussed above). Display device 1603 may include any visual indicators, such as a heads-up display, a computer monitor, a projector, a touchscreen display, a liquid crystal display (LCD), a light-emitting diode display, or a flat panel display, for example.

Computing device 1600 may include an audio output device 1604 (or corresponding interface circuitry, as discussed above). Audio output device 1604 may include any device that generates an audible indicator, such as speakers, headsets, or earbuds, for example.

Computing device 1600 may include an audio input device 1610 (or corresponding interface circuitry, as discussed above). Audio input device 1610 may include any device that generates a signal representative of a sound, such as microphones, microphone arrays, or digital instruments (e.g., instruments having a musical instrument digital interface (MIDI) output).

Computing device 1600 may include a GPS device 1609 (or corresponding interface circuitry, as discussed above). GPS device 1609 may be in communication with a satellite-based system and may receive a location of computing device 1600, as known in the art.

Computing device 1600 may include other output device 1605 (or corresponding interface circuitry, as discussed above). Examples of the other output device 1605 may include an audio codec, a video codec, a printer, a wired or wireless transmitter for providing information to other devices, or an additional storage device.

Computing device 1600 may include other input device 1611 (or corresponding interface circuitry, as discussed above). Examples of the other input device 1611 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1600 may include a security interface device 1612. Security interface device 1612 may include any device that provides security measures for computing device 1600 such as intrusion detection, biometric validation, security encode or decode, access list management, malware detection, or spyware detection.

Computing device 1600, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-16. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes source and drain regions in a transistor structure and a channel material therebetween, a gate structure over the channel material and between the source and drain regions, the gate structure including a dielectric layer between a gate metal and the channel material, and a first layer between the gate structure and the source region or the drain region, wherein a first portion of the first layer is over an upper surface of the channel material, a second portion of the first layer is under a lower surface of the channel material, and the first portion of the first layer has a first composition substantially the same as a second composition of the second portion of the first layer.

In one or more second embodiments, further to the first embodiments, a plurality of nanoribbons include the channel material between the source and drain regions, a first of the nanoribbons includes the upper surface of the channel material and is adjacent the first portion of the first layer, a second of the nanoribbons is adjacent the second portion of the first layer, a third portion of the first layer is between the first and second of the nanoribbons and between the first and second portions of the first layer, and the third portion of the first layer has a third composition substantially the same as the first and second compositions.

In one or more third embodiments, further to the first or second embodiments, the gate metal has a first height over the plurality of nanoribbons, the upper surface of the first of the nanoribbons has a second height, and the first and second heights are within twice a pitch of the nanoribbons between adjacent ones of the plurality of nanoribbons.

In one or more fourth embodiments, further to the first through third embodiments, the first and second compositions both include silicon, oxygen, and nitrogen.

In one or more fifth embodiments, further to the first through fourth embodiments, a second layer is between the gate structure and the source region or the drain region adjacent both the first and second portions of the first layer, and the second layer includes silicon, oxygen, and carbon.

In one or more sixth embodiments, further to the first through fifth embodiments, the second layer includes an atomic composition of at least thirty percent silicon, at least fifteen percent oxygen, at least five percent carbon, and less than five percent nitrogen, and the first and second portions of the first layer include atomic compositions of at least thirty percent silicon, at least fifteen percent oxygen, at least ten percent nitrogen, and less than five percent carbon.

In one or more seventh embodiments, further to the first through sixth embodiments, an integrated circuit (IC) die includes the transistor structure, and the IC die is coupled to a substrate and a power supply through the substrate.

In one or more eighth embodiments, an apparatus includes an integrated circuit (IC) die coupled to a substrate, source and drain regions in the IC die and a plurality of nanoribbons therebetween, a gate structure over the nanoribbons and between the source and drain regions, the gate structure including a dielectric layer between a gate metal and individual ones of the nanoribbons, and first and second layers between the source and drain regions, wherein the gate structure is between the first and second layers, first portions of the first and second layers are adjacent an upper surface of a first one of the nanoribbons, second portions of the first and second layers are adjacent a lower surface of a second one of the nanoribbons, and the first portions of the first and second layers have a first composition substantially the same as a second composition of the second portions of the first and second layers.

In one or more ninth embodiments, further to the eighth embodiments, a third layer is between the gate structure and the source region or the drain region adjacent both the first and second portions of the first layer or the second layer, the first and second layers both include atomic compositions of at least thirty percent silicon, at least fifteen percent oxygen, and at least ten percent nitrogen, and less than five percent carbon, and the third layer includes atomic compositions of at least thirty percent silicon, at least fifteen percent oxygen, at least five percent carbon, and less than five percent nitrogen.

In one or more tenth embodiments, further to the eighth or ninth embodiments, the gate metal has a first height over the plurality of nanoribbons, the upper surface of the first one of the nanoribbons has a second height, and a difference between the first and second heights is less than 15 nm.

In one or more eleventh embodiments, a method includes forming or receiving a fin including a stack of materials, the stack including at least a first mask material layer in contact with a sacrificial material layer over a transistor channel material layer, recessing an exposed first face of the sacrificial material layer, wherein the recessing removes a first portion of the sacrificial material layer, retains a second portion of the sacrificial material layer, and exposes a second face of the sacrificial material layer, depositing an insulator layer over the second face of the sacrificial material layer, forming an opening between the first mask material layer and the transistor channel material layer by removing the second portion of the sacrificial material layer, and depositing a gate metal in the opening, wherein an upper surface of the gate metal over the transistor channel material layer is under a lower surface of the first mask material layer

In one or more twelfth embodiments, further to the eleventh embodiments, the method also includes forming the stack of materials, wherein the forming the stack of materials includes epitaxially depositing the sacrificial material layer.

In one or more thirteenth embodiments, further to the eleventh or twelfth embodiments, the method also includes forming the stack of materials, wherein the forming the stack of materials includes depositing a plurality of sacrificial material layers interleaved with a plurality of transistor channel material layers, the sacrificial material layer in contact with the first mask material layer is a first sacrificial material layer in the plurality of sacrificial material layers, the transistor channel material layer is a first transistor channel material layer in the plurality of transistor channel material layers, the forming the fin from the stack of materials forms a plurality of nanoribbons from the plurality of transistor channel material layers, and the first sacrificial material layer is over a top one of the plurality of nanoribbons, between the top one of the nanoribbons and the first mask material layer

In one or more fourteenth embodiments, further to the eleventh through thirteenth embodiments, the method also includes etching the fin, wherein the etching the fin exposes a plurality of first faces of the plurality of sacrificial material layers, wherein the recessing the exposed first face of the first sacrificial material layer concurrently recesses the plurality of first faces of the plurality of sacrificial material layers and retains a plurality of second portions of the plurality of sacrificial material layers, and the depositing the insulator layer over the second face of the first sacrificial material layer concurrently deposits a plurality of insulator layers over a plurality of second faces of the plurality of sacrificial material layers, wherein individual ones of the plurality of insulator layers have a substantially same composition.

In one or more fifteenth embodiments, further to the eleventh through fourteenth embodiments, forming the stack of materials includes depositing the first sacrificial material layer to a first thickness greater than a second thickness of a second sacrificial material layer.

In one or more sixteenth embodiments, further to the eleventh through fifteenth embodiments, the depositing the gate metal in the opening deposits the gate metal to a first height above the lower surface of the first mask material layer, and the method also includes recessing the gate metal down to a second height at the first mask material layer or at a second mask material layer over the first mask material layer.

In one or more seventeenth embodiments, further to the eleventh through sixteenth embodiments, the method also includes recessing the gate metal down to a third height below the first mask material layer.

In one or more eighteenth embodiments, further to the eleventh through seventeenth embodiments, the method also includes forming a metal contact to the gate metal through at least the first mask material layer.

In one or more nineteenth embodiments, further to the eleventh through eighteenth embodiments, the method also includes forming a sacrificial structure over and across the fin, wherein the first mask material layer and the sacrificial material layer are over the transistor channel material layer and between the sacrificial structure and the transistor channel material layer, and the sacrificial structure is adjacent a sidewall of the fin, depositing a dielectric layer over the sacrificial structure and the fin, depositing a third mask material over the sacrificial structure and a first section of the dielectric layer, and etching the fin, including removing a second section of the dielectric layer not masked by the third mask material and retaining the first section of the dielectric layer adjacent the sacrificial structure, wherein the deposited insulator layer over the second face of the sacrificial material layer is adjacent the retained first section of the dielectric layer.

In one or more twentieth embodiments, further to the eleventh through nineteenth embodiments, the depositing the insulator layer over the second face of the sacrificial material layer includes selectively depositing the insulator layer on the sacrificial material layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
source and drain regions in a transistor structure and a channel material therebetween;
a gate structure over the channel material and between the source and drain regions, the gate structure comprising a dielectric layer between a gate metal and the channel material; and
a first layer between the gate structure and the source region or the drain region, wherein a first portion of the first layer is over an upper surface of the channel material, a second portion of the first layer is under a lower surface of the channel material, and the first portion of the first layer has a first composition substantially the same as a second composition of the second portion of the first layer.

2. The apparatus of claim 1, wherein a plurality of nanoribbons comprise the channel material between the source and drain regions, a first of the nanoribbons comprises the upper surface of the channel material and is adjacent the first portion of the first layer, a second of the nanoribbons is adjacent the second portion of the first layer, a third portion of the first layer is between the first and second of the nanoribbons and between the first and second portions of the first layer, and the third portion of the first layer has a third composition substantially the same as the first and second compositions.

3. The apparatus of claim 2, wherein the gate metal has a first height over the plurality of nanoribbons, the upper surface of the first of the nanoribbons has a second height, and the first and second heights are within twice a pitch of the nanoribbons between adjacent ones of the plurality of nanoribbons.

4. The apparatus of claim 1, wherein the first and second compositions both comprise silicon, oxygen, and nitrogen.

5. The apparatus of claim 1, wherein a second layer is between the gate structure and the source region or the drain region adjacent both the first and second portions of the first layer, and the second layer comprises silicon, oxygen, and carbon.

6. The apparatus of claim 5, wherein the second layer comprises an atomic composition of at least thirty percent silicon, at least fifteen percent oxygen, at least five percent carbon, and less than five percent nitrogen, and the first and second portions of the first layer comprise atomic compositions of at least thirty percent silicon, at least fifteen percent oxygen, at least ten percent nitrogen, and less than five percent carbon.

7. The apparatus of claim 1, wherein an integrated circuit (IC) die comprises the transistor structure, and the IC die is coupled to a substrate and a power supply through the substrate.

8. An apparatus, comprising:
an integrated circuit (IC) die coupled to a substrate;
source and drain regions in the IC die and a plurality of nanoribbons therebetween;
a gate structure over the nanoribbons and between the source and drain regions, the gate structure comprising a dielectric layer between a gate metal and individual ones of the nanoribbons; and
first and second layers between the source and drain regions, wherein the gate structure is between the first and second layers, first portions of the first and second layers are adjacent an upper surface of a first one of the nanoribbons, second portions of the first and second layers are adjacent a lower surface of a second one of the nanoribbons, and the first portions of the first and second layers have a first composition substantially the same as a second composition of the second portions of the first and second layers.

9. The apparatus of claim 8, wherein:
a third layer is between the gate structure and the source region or the drain region adjacent both the first and second portions of the first layer or the second layer;
the first and second layers both comprise atomic compositions of at least thirty percent silicon, at least fifteen percent oxygen, and at least ten percent nitrogen, and less than five percent carbon; and
the third layer comprises atomic compositions of at least thirty percent silicon, at least fifteen percent oxygen, at least five percent carbon, and less than five percent nitrogen.

10. The apparatus of claim 9, wherein the gate metal has a first height over the plurality of nanoribbons, the upper surface of the first one of the nanoribbons has a second height, and a difference between the first and second heights is less than 15 nm.

11. A method, comprising:
forming or receiving a fin comprising a stack of materials, the stack comprising at least a first mask material layer in contact with a sacrificial material layer over a transistor channel material layer;
recessing an exposed first face of the sacrificial material layer, wherein the recessing removes a first portion of the sacrificial material layer, retains a second portion of the sacrificial material layer, and exposes a second face of the sacrificial material layer;
depositing an insulator layer over the second face of the sacrificial material layer;
forming an opening between the first mask material layer and the transistor channel material layer by removing the second portion of the sacrificial material layer; and
depositing a gate metal in the opening, wherein an upper surface of the gate metal over the transistor channel material layer is under a lower surface of the first mask material layer.

12. The method of claim 11, further comprising forming the stack of materials, wherein the forming the stack of materials comprises epitaxially depositing the sacrificial material layer.

13. The method of claim 11, further comprising forming the stack of materials, wherein:
the forming the stack of materials comprises depositing a plurality of sacrificial material layers interleaved with a plurality of transistor channel material layers;
the sacrificial material layer in contact with the first mask material layer is a first sacrificial material layer in the plurality of sacrificial material layers;
the transistor channel material layer is a first transistor channel material layer in the plurality of transistor channel material layers;
the forming the fin from the stack of materials forms a plurality of nanoribbons from the plurality of transistor channel material layers; and
the first sacrificial material layer is over a top one of the plurality of nanoribbons, between the top one of the nanoribbons and the first mask material layer.

14. The method of claim 13, further comprising etching the fin, wherein the etching the fin exposes a plurality of first faces of the plurality of sacrificial material layers, wherein:
the recessing the exposed first face of the first sacrificial material layer concurrently recesses the plurality of first faces of the plurality of sacrificial material layers and retains a plurality of second portions of the plurality of sacrificial material layers; and
the depositing the insulator layer over the second face of the first sacrificial material layer concurrently deposits a plurality of insulator layers over a plurality of second faces of the plurality of sacrificial material layers, wherein individual ones of the plurality of insulator layers have a substantially same composition.

15. The method of claim 13, wherein forming the stack of materials comprises depositing the first sacrificial material layer to a first thickness greater than a second thickness of a second sacrificial material layer.

16. The method of claim 11, wherein the depositing the gate metal in the opening deposits the gate metal to a first height above the lower surface of the first mask material layer, and further comprising recessing the gate metal down to a second height at the first mask material layer or at a second mask material layer over the first mask material layer.

17. The method of claim 16, further comprising recessing the gate metal down to a third height below the first mask material layer.

18. The method of claim 11, further comprising forming a metal contact to the gate metal through at least the first mask material layer.

19. The method of claim 11, further comprising:
forming a sacrificial structure over and across the fin, wherein the first mask material layer and the sacrificial material layer are over the transistor channel material layer and between the sacrificial structure and the transistor channel material layer, and the sacrificial structure is adjacent a sidewall of the fin;
depositing a dielectric layer over the sacrificial structure and the fin;
depositing a third mask material over the sacrificial structure and a first section of the dielectric layer; and
etching the fin, comprising removing a second section of the dielectric layer not masked by the third mask material and retaining the first section of the dielectric layer adjacent the sacrificial structure, wherein the deposited insulator layer over the second face of the sacrificial material layer is adjacent the retained first section of the dielectric layer.

20. The method of claim 11, wherein the depositing the insulator layer over the second face of the sacrificial material layer comprises selectively depositing the insulator layer on the sacrificial material layer.
